(19) United States
(12) Patent Application Publication
(10) Pub. No.: US 2006/0291178 A1
(43) Pub. Date: Dec. 28, 2006

(54) High frequency circuit module

(75) Inventor: Cheng-Yen Shih, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS INC.

(21) Appl. No.: 11/472,480

(22) Filed: Jun. 22, 2006

(30) Foreign Application Priority Data
Jun. 27, 2005 (TW) 94121368

(51) Int. Cl. H05K 7/06

(52) U.S. Cl. 361/780; 361/794; 361/795; 174/257; 174/258; 174/255

(57) ABSTRACT

A circuit module with reduced parasitical capacitance. The circuit module comprises a first circuit structure, a second circuit structure, a block layer, a first ground layer, and a second ground layer. The first circuit structure is disposed in a first substrate. The second circuit structure is disposed in a second substrate, and forms a stacked substrate with the first circuit structure. The block layer contacts the stacked substrate. The first ground layer is between the first circuit structure and the second circuit structure. And the second ground layer is electrically coupled to the first ground layer through a connecting segment.

### BACKGROUND

The invention relates in general to a high frequency circuit module, and in particular, to ground layers in a high frequency circuit module.

As technology advances, mobile telecommunication devices continue to shrink in scale and increase in circuit density. Consequently leakage current is a significant issue. To resolve the leakage current issue high dielectric material is utilized as a circuit substrate. This complicates high frequency circuit design.

FIG. 1A is a conventional high frequency circuitry 100 comprising substrate 101, ground layers 102 and 103, and stripline 104. FIG. 1B shows an equivalent circuit of FIG. 1A, the stripline 104 has a series connected inductance L and resistance R effect at the direction X of a signal communication, and a parallel connected conductance G and capacitance C effect at the direction Z of the signal communication. The parasitical parallel connected capacitance C is closely related with a dielectric constant ε of substrate 101. The parasitical capacitance C increases with higher dielectric constant ε, and the impedance of the stripline 104 decreases at the same time. The result will limit the design of the high frequency circuitry 100.

Moreover, an even thinner line width of the stripline has to be employed to maintain the original impedance, but the minimum line width is limited by current technology.

A multi-layer high dielectric constant substrate is commonly used to further enhance circuit density, but the substrate has severer parasitical capacitance effect. FIG. 2 is a cross section of a conventional high frequency circuit module 200, comprising multi-layer high dielectric constant substrate 201, which comprises circuit structures 204 and 205 constituting striplines on substrate 201. A main reference ground layer 202 is disposed an under-surface of the lowest layer of substrate 201 in high frequency circuit module 200. To prevent signal interference between the circuit structures 204 and 205, the ground layer 203 is deposited therebetween and serves as an electric field shield. FIG. 3 is an exemplary distribution diagram of electric field for circuit structures in FIG. 2. In view of the stripline 205a in the circuit structure 205, the electric field is concentrated between stripline 205a and ground layer 203 while only a weak electric field is present on the top, i.e., no ground layer is present, resulting in a smaller parasitical capacitance. On the other hand, the stripline 204a in the circuit structure 204 is between two ground layers 203 and 202, wherein the ground layer 203 doesn't connect with the ground layer2O2, and the ground layer 203 and 202 both have high dielectric constant ε1. Then the electric field of the stripline 204a is concentrated on both sides, and brings a very large parasitical capacitance.

Multi-layer circuit structures require more field shielding ground layers. The result has a severer parasitical capacitance effect, and degrade the performance of the high frequency circuit modules. To counter the parasitical capacitance issue, the line width of striplines may be reduced. Unfortunately the minimum line width is limited by current technology.

### SUMMARY

The invention is directed to a circuit module with less parasitical capacitance.

According to one embodiment of the invention, a circuit module with less parasitical capacitance is provided. The circuit module comprises at least one first circuit structure, at least one second circuit structure, at least one block layer, at least one first ground layer, and at least one second ground layer. The first circuit structure is disposed in at least one first substrate. The second circuit structure is disposed in at least one second substrate. The first substrate and the second substrate form a stacked substrate. One side of the block layer contacts with the stacked substrate. The first ground layer is between the first circuit structure and the second circuit structure. And the second ground layer is on another side of the block layer, and is electrically coupled to the first ground layer.

In another embodiment of the invention, a circuit module contacting one side of an external system is described. The circuit module comprises at least one first circuit structure, at least one second circuit structure, at least one block layer, and at least one first ground layer. The first circuit structure is disposed in at least one first substrate. The second circuit structure is disposed in at least one second substrate. The first substrate and the second substrate form a stacked substrate. One side of the stacked substrate contacts with the side of the external system. The first ground layer is between the first circuit structure and the second circuit structure. The first ground layer is electrically coupled to a second ground layer which on another side of the external system. The dielectric constant of the external system is lower than those of the first circuit structure and the second circuit structure.

### BRIEF DESCRIPTION OF THE DRAWINGS

The invention will become more fully understood from the detailed description, given hereinbelow, and the accompanying drawings. The drawings and description are provided for purposes of illustration only and, thus, are not intended to be limiting of the present invention.

FIG. 1A is a conventional high frequency circuitry.

FIG. 1B shows an equivalent circuit of FIG. 1A

FIG. 2 is a cross section of a conventional high frequency circuit module.

FIG. 3 is an exemplary field distribution diagram of electric field for circuit structures in FIG. 2.

FIG. 4 is a cross section of communication circuit module, according to an embodiment of the invention.

FIG. 5 shows the electric field of communication circuit module 400 in FIG.4.

FIG. 6 shows a cross section of communication circuit module and external system, according to another embodiment in the invention.

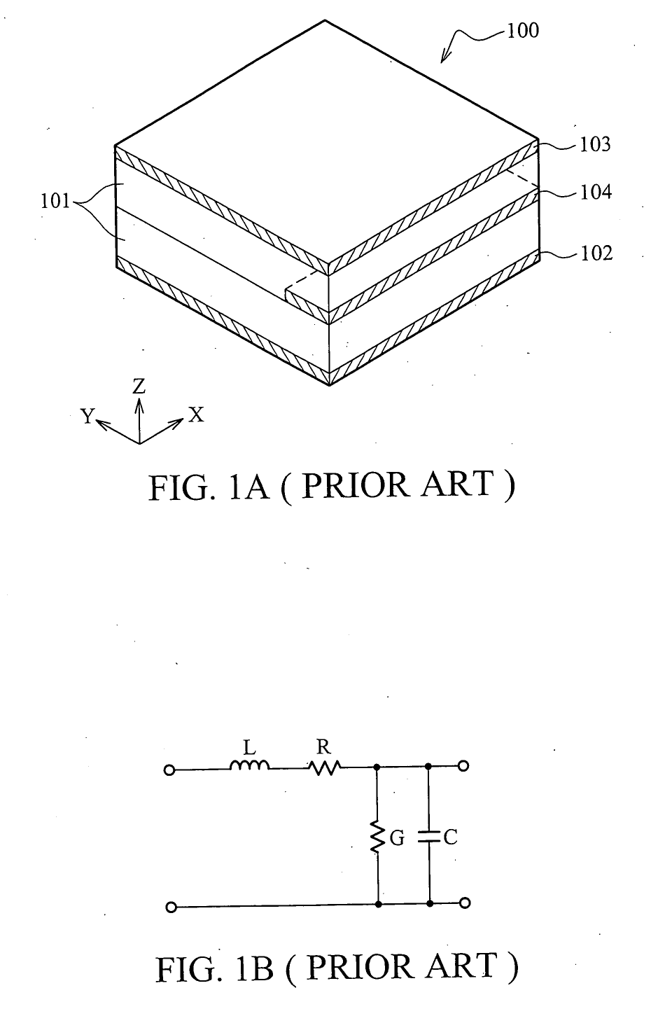

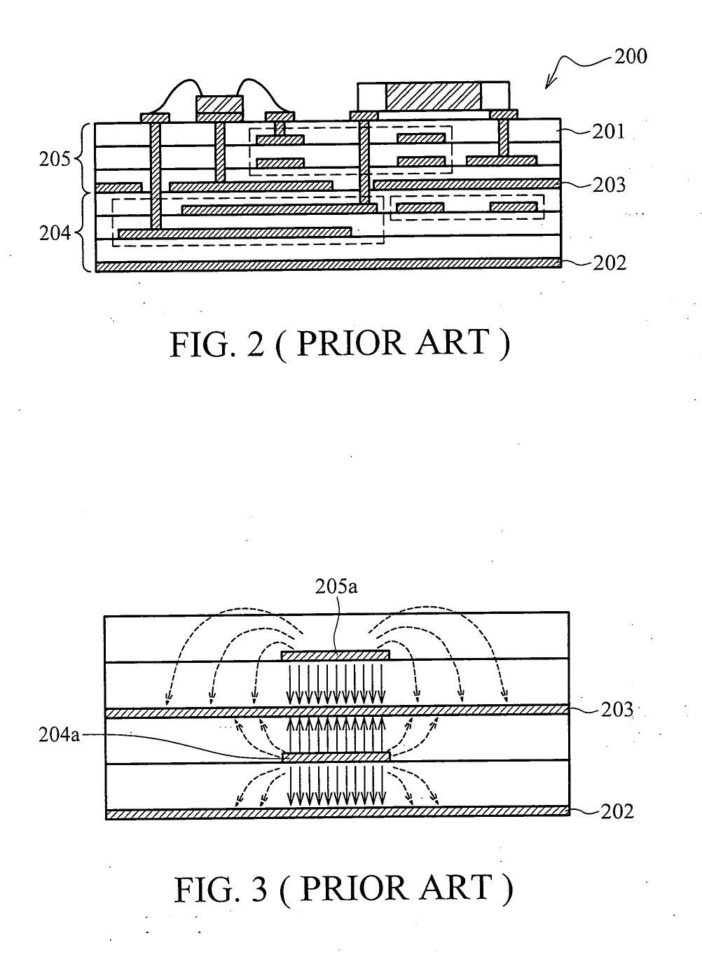

### DETAILED DESCRIPTION

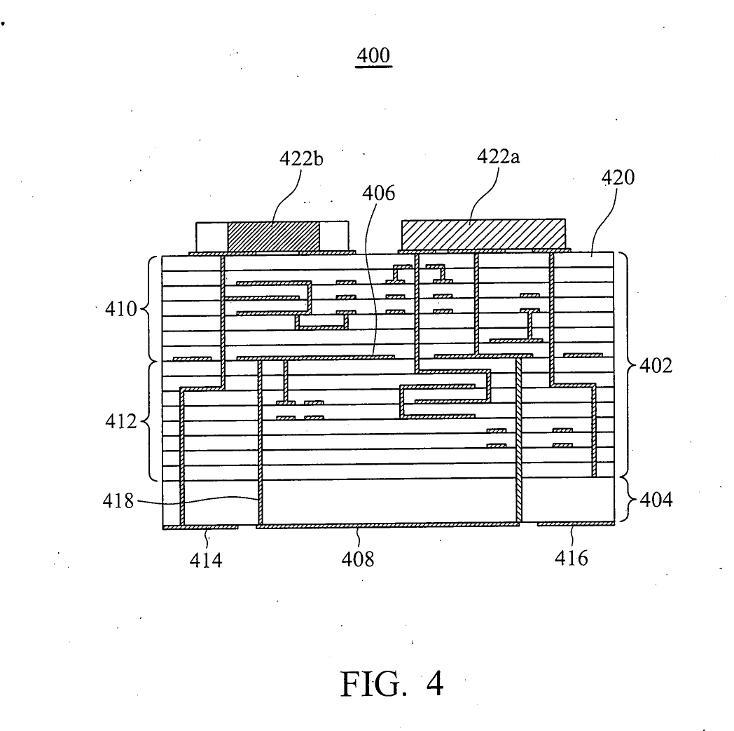

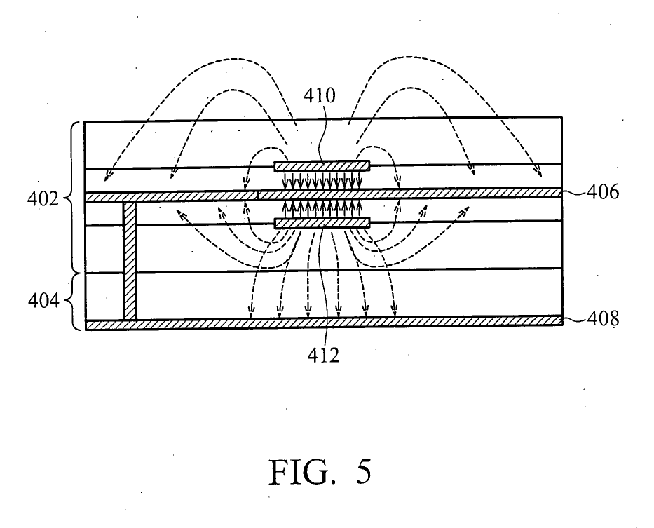

FIG. 4 is a cross section of a communication circuit module 400, according to an embodiment of the invention. FIG. 5 depicts the electric field of the communication circuit module 400 in FIG.4.

Referring now to FIG. 4, a communication circuit module 400 comprises a circuit region 402 and a block layer 404, wherein the dielectric constant of the block layer 404 is lower than those of a substrates 420 of the circuit region 402. The communication circuit module 400 may be a high frequency circuit module, a Bluetooth module, or a wireless communication module.

The circuit region 402 is formed by stacked substrates 420, and comprises at least one circuit structure 410, 412, and at least one ground layer 406. The material of the substrate 420 may be a low dielectric material (low-k dielectrics), ceramic material, organic polymer material, silicon material or a high dielectric material (high-k dielectrics). The ground layer 406 is disposed between the circuit structures 410 and 412, which may be a digital circuit structures, a high-power circuit structures, a low-power circuit structures, an analog circuit structures, or a stripline circuit structures. Furthermore, the elements 422a and 422b are formed on circuit region 402 and electrically coupled with the circuit structure 410. The elements 422a and 422b may be resistor, capacitor, inductor, microprocessor, controller, or other un-embedded elements.

One side of the block layer 404 is contacted with one side of the top or bottom substrate 420 of the circuit region 402, and another side of the block layer 404 has a ground layer 408 and connection pads 414 and 416. The dielectric constant of the block layer 404 is lower than that of the top or bottom substrate 420, and may be any low dielectric material, ceramic material, high molecular material, silicon material or high dielectric material.

The ground layer 408 is coupled to the ground layer 406 through at least one connecting segment 418, thus the ground layer 408 is extended to at least one region which doesn't has the circuit structures in circuit region 402, thereby the dimension of the effective ground layer will increase without increasing that of communication circuit module 400. Consequently, the ground layer 408 can be an electromagnetic shield between the circuit structures 410 and 412 by the ground layer 406, and prevent the interference between the circuit structures 410 and 412. The material of ground layers 406 and 408 may be metal, carbon fiber or other conductive material.

The circuit structures 410 and 412 are electrically coupled to the external system by the connection pads 414 and 416.

FIG. 5, shows a field distribution diagram of electric field. The dielectric constant of the substrate 420 with the circuit structure 410 is greater than that of the ambient air, which is approximately 1, thus the electric field of circuit structure 410 is concentrated at ground layer 406. Similarly, the dielectric constant of the substrate 420 with the circuit structure 412 is larger than that of block layer 404. Thus the electric field of circuit structure 412 is concentrated at ground layer 406. In this embodiment, a current in ground layer 406 formed by the electric field in between the circuit structures 410 and 412 can be conducted away from the communication circuit module 400 through the connecting segments 418 and the the ground layer 408 , thereby reducing parasitical capacitance of the communication circuit module 400.

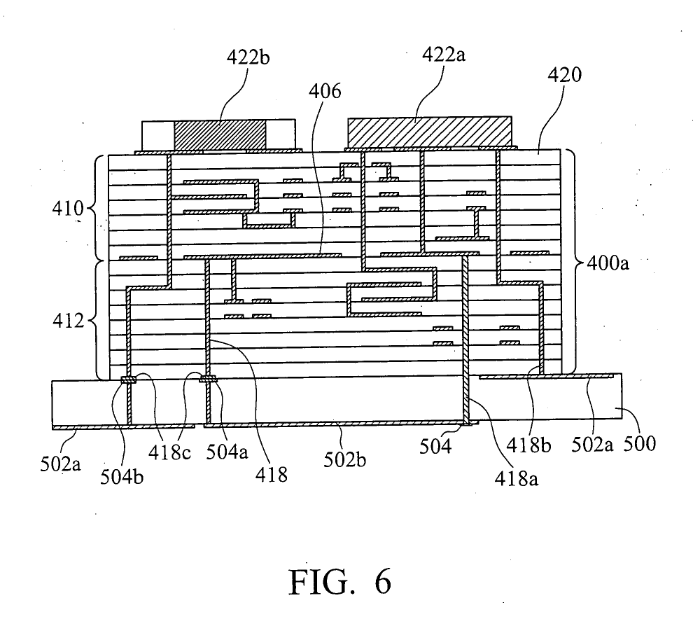

FIG. 6 shows a cross section of a communication circuit module 400a and an external system 500, according to another embodiment in the invention. In this embodiment, the dielectric constant of a substrate 420 of the communication circuit module 400a is higher than that of the external system 500.

The surface of the external system 500 comprises a circuit structure 502a and a ground layer 502b, both disposed on the same or different surfaces of the external system 500. The external system 500 may be a printed circuit board.

The circuit structures 410 and 412 of the communication module 400a are coupled to the circuit structure 502a of external system 500 by connecting segment 418b, connection pads 418c and 504b, or connecting to the external system 500 and fixed by the connection pads. Ground layer 406 of the communication circuit module 400a is coupled to the ground layer 502b of the external system 500 through connecting segments 418 and 418a, to provide a complete ground layer. Connection between the ground layers 406 and 502b may be accomplished by connecting segments 418 and 418a directly, coupling connection pads 418c and 504a electrically, or connecting segment 418a penetrating ground layer 502b and secured by connection pad 504.

In this embodiment, some part of the ground layer is on the external system, and the block layer of the circuit module has a lower dielectric constant than that of the external system, resulting in reduced parasitical capacitance between the modules, and reduced a dimension of the circuit module.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A communication circuit module, comprising:
a first circuit structure disposed in at least one first substrate;
a second circuit structure disposed in at least one second substrate and forming a stacked substrate with the first circuit structure;
at least one block layer having one side to contact the stacked substrate;
a first ground layer disposed between the first circuit structure and the second circuit structure; and
a second ground layer disposed on another side of the block layer and electrically coupled to the first ground layer.

2. The module of claim 1, wherein the material of the first substrate or the second substrate is a low dielectric material, a ceramic material, an organic high molecular material, a silicon material, or a high dielectric material.

3. The module of claim 1, wherein the first circuit structure or the second circuit structure is a digital circuit structure, a high-power circuit structure, a low-power circuit structure, an analog circuit structure or a stripline.

4. The module of claim 1, further comprising a resistor, an inductor, a capacitor, a central processing unit, or a controller on the stacked substrate.

5. The module of claim 1, wherein the material of the first ground layer or the second ground layer is a metal, a carbon fiber, or a conductive material.

6. The module of claim 1, wherein the material of the block layer is a low dielectric material, a ceramic material, an organic high molecular material, a silicon material, or a high dielectric material.

7. The module of claim 1, wherein the block layer is a printed circuit board.

8. The module of claim 1, further comprising a connection pad on the block layer electrically coupled with the first circuit structure and the second circuit structure.

9. The module of claim 1, wherein the block layer has a dielectric constant lower than those of the first substrate and the second substrate.

10. A communication circuit module disposed on an external system, comprising:
a first circuit structure disposed in at least one first substrate;
a second circuit structure disposed in at least one second substrate and forming a stacked substrate with the first circuit structure; and
a first ground layer between the first circuit structure and the second circuit structure;
wherein the first ground layer is electrically coupled to a second ground layer of the external system.

11. The module of claim 10, wherein the material of the first substrate or the second substrate is a low dielectric material, a ceramic material, an organic high molecular material, a silicon material, or a high dielectric material.

12. The module of claim 10, wherein the first circuit structure or the second circuit structure is a digital circuit structure, a high-power circuit structure, a low-power circuit structure, an analog circuit structure or a stripline.

13. The module of claim 10, further comprising a resistor, an inductor, a capacitor, a central processing unit, or a controller disposed on the stacked substrate.

14. The module of claim 10, wherein the material of the first ground layer or the second ground layer is a metal, a carbon fiber, or a conductive material.

15. The module of claim 10, wherein the material of the external system is a low dielectric material, a ceramic material, an organic high molecular material, a silicon material, or a high dielectric material.

16. The module of claim 10, wherein the external system is a printed circuit board.

17. The module of claim 10, further comprising a first connection pad on the stacked substrate electrically coupled to the first circuit structure and the second circuit structure.

18. The module of claim 17, further comprising a second connection pad on a side of the external system coupled with the first connection pad.

19. The module of claim 10, further comprising a third connection pad disposed in the external system coupled with the first circuit structure and the second circuit structure.

20. The module of claim 10, wherein the dielectric constant of the external system is lower than those of the first substrate and the second substrate thereof.
